(19) United States
(12) Patent Application Publication
(10) Pub. No.: US 2014/0203356 A1
(43) Pub. Date: Jul. 24, 2014

(54) SEMICONDUCTOR DEVICE INCLUDING VERTICAL SEMICONDUCTOR ELEMENT

(71) Applicants: Yuma Kagata, Kariya-city (JP); Nozomu Akagi, Nukata-gun (JP)

(72) Inventors: Yuma Kagata, Kariya-city (JP); Nozomu Akagi, Nukata-gun (JP)

(73) Assignee: DENSO CORPORATION, Kariya-city, Aichi-pref. (JP)

(21) Appl. No.: 14/239,291

(22) PCT Filed: Aug. 30, 2012
(86) PCT No.: PCT/JP2012/005463

§ 371 Date: Feb. 18, 2014

(30) Foreign Application Priority Data
Sep. 27, 2011 (JP) 2011-210676
Jul. 20, 2012 (JP) 2012-161523

(51) Int. Cl. H01L 29/10; H01L 29/66; H01L 29/78

(52) U.S. Cl. CPC H01L 29/1045; H01L 29/7813; H01L 29/66734
USPC 257/330; 438/270

(57) ABSTRACT

A semiconductor device including a vertical semiconductor element has a trench gate structure and a dummy gate structure. The trench gate structure includes a first trench that penetrates a first impurity region and a base region to reach a first conductivity-type region in a super junction structure. The dummy gate structure includes a second trench that penetrates the base region reach the super junction structure and is formed to be deeper than the first trench.

### CROSS REFERENCE TO RELATED APPLICATION

The present disclosure is based on Japanese Patent Application No. 2011-210676 filed on Sep. 27, 2011 and Japanese Patent Application No. 2012-161523 filed on Jul. 20, 2012, the disclosures of which are incorporated herein by reference.

### TECHNICAL FIELD

The present disclosure relates to a semiconductor device including a vertical semiconductor element.

### BACKGROUND ART

In a semiconductor device including a vertical MOS transistor, holes are normally extracted from a p type base region. However, in a case where a voltage drop in an extraction path is too large, an avalanche current flows toward an n⁺ type source region to operate a parasitic bipolar transistor. Thus, an avalanche resistance is reduced. In order to improve the avalanche resistance, it is necessary not to operate the parasitic bipolar transistor formed by the n⁺ type source region, the p type base region, and an n⁻ type drift layer.

In order to achieve that, conventionally, a structure in which p type impurities are deeply diffused between adjacent trench gates to form a high-concentration p⁺ type body layer so as to restrict operation of the parasitic bipolar transistor has been proposed (for example, Patent Document 1). Using the above-described structure, an avalanche breakdown, which has occurred at a lower portion of the trench gate on which electric field concentrates in a conventional structure, can be caused on a joint surface of the p⁺ type body layer and the n⁻ type drift layer. Thus, holes, which cause operation of the parasitic bipolar transistor, can be extracted to a source electrode through a high concentration (low resistance) path so as not to operate the parasitic bipolar transistor.

However, in a case where the above-described structure is applied to a vertical MOS transistor having a super junction structure, a high-temperature and long-time heat treatment is necessary to diffuse a high-concentration p⁺ type body layer to be deeper than a trench filled with a gate electrode. By the heat treatment, impurities in an n type region (n type column) which is a current path of the super junction structure and a p type region (p type column) for charge compensation are diffused each other, charges are compensated, and an on-resistance increases.

### PRIOR ART DOCUMENTS

### Patent Document

[Patent Document 1] JP-A-2010-010556

### SUMMARY OF INVENTION

An object of the present disclosure is to restrict increase in on-resistance in a semiconductor device that includes a vertical semiconductor element having a super junction structure.

A semiconductor device according to an aspect of the present disclosure includes a vertical semiconductor element that includes a semiconductor substrate, a drift layer, a second conductivity-type region, a base region, a first impurity region, a first trench, a first gate insulation film, a gate electrode, a contact region, a front surface electrode, a rear surface electrode, a second trench, a second gate insulation film, and a dummy gate electrode and applies electric current between the front surface electrode and a rear surface electrode based on voltage application to the gate electrode.

The semiconductor substrate has a first conductivity-type or a second conductivity-type and has a main surface and a rear surface. The drift layer has the first conductivity-type and is formed to the main surface side of the semiconductor substrate. The second conductivity-type region is formed to the main surface side of the semiconductor substrate and is arranged alternately with the drift layer to form a super junction structure. The base region has the second conductivity-type and is formed above the super junction structure. The first impurity region has the first conductivity-type, is formed at a surface portion of the base region, and has an impurity concentration higher than the drift layer. The first trench penetrates the first impurity region and the base region to reach the first conductivity-type region in the super junction structure. The first gate insulation film is formed on an inner wall of the first trench. The gate electrode is formed on a surface of the first gate insulation film and fills the first trench to form a trench gate structure. The contact region has the second conductivity-type and is formed at the surface portion of the base region on an opposite side of the first impurity region from the first trench. The contact region has an impurity concentration higher than the base region. The front surface electrode is electrically connected to the first impurity region and the contact region. The rear surface electrode is electrically connected to the semiconductor substrate. The second trench penetrates the base region to reach the super junction structure and is formed to be deeper than the first trench. The second gate insulation film is formed on an inner wall of the second trench. The dummy gate electrode is formed on a surface of the second gate insulation film and fills the second trench to form a dummy gate structure.

In the semiconductor device, the second trench forming the dummy gate structure is formed to be deeper than the first trench forming the trench gate structure. Thus, an avalanche resistance can be improved and an increase in on-resistance can be restricted.

In a manufacturing method of a semiconductor device including a vertical semiconductor element according to another aspect of the present disclosure, a semiconductor substrate of a first conductivity-type or a second conductivity-type having a main surface and a rear surface is prepared. A drift layer of the first conductivity-type is formed to the main surface side of the semiconductor substrate and a second conductivity-type region is formed in the drift layer to form a super junction structure in which a first conductivity-type region provided by a remaining region of the drift layer at which the second conductivity-type region is not formed and the second conductivity-type region are alternately arranged. A base region of the second conductivity-type is formed above the super junction structure. A mask having a first opening portion and a second opening portion wider than the first opening portion is arranged above the base region and a first trench having a width corresponding to the first opening portion and a second trench having a width corresponding to the second opening portion and deeper than the first trench are formed by etching using the mask. Inner walls of the first and second trenches are covered by gate insulation films. A trench gate structure is formed by forming a gate electrode on a surface of the gate insulation film in the first trench, and a dummy structure is formed by forming a dummy gate electrode on a surface of the gate insulation film in the second trench. A first impurity region of the first conductivity-type having an impurity concentration higher than the drift layer is formed at a surface portion of the base region. A contact region of the second conductivity-type is formed at the surface portion of the base region on an opposite side of the first impurity region from the first trench. The contact region has an impurity concentration higher than the base region. A front surface electrode electrically connected to the first impurity region and the contact region is formed. A rear surface electrode electrically connected to the semiconductor substrate is formed.

As described above, in a case where a width of the second opening portion for forming the second trench is set to be wider than the first opening portion for forming the first trench, the second trench is formed deeper than the first trench by a micro loading effect when forming the trenches. Accordingly, the semiconductor device that can restrict an increase in on-resistance can be manufactured.

### BRIEF DESCRIPTION OF DRAWINGS

The above and other objects, features and advantages of the present disclosure will become more apparent from the following detailed description made with reference to the accompanying drawings. In the drawings:

FIG. 1 is a cross-sectional view illustrating a cell region Rc of a semiconductor device including a vertical MOS transistor according to a first embodiment of the present disclosure;

FIG. 2 is a diagram illustrating a layout of the semiconductor device illustrated in FIG. 1;

FIG. 3(a) through FIG. 3(c) are cross-sectional views illustrating manufacturing processes of the semiconductor device including the vertical MOS transistor and illustrated in FIG. 1;

FIG. 4(a) through FIG. 4(c) are cross-sectional views illustrating manufacturing processes, which follow FIG. 3(c), of the semiconductor device including the vertical MOS transistor;

FIG. 5(a) through FIG. 5(c) are cross-sectional views illustrating manufacturing processes, which follow FIG. 4(c), of the semiconductor device including the vertical MOS transistor;

FIG. 6 is a cross-sectional view illustrating a cell region Rc of a semiconductor device including a vertical MOS transistor according to a second embodiment of the present disclosure;

FIG. 7(a) and FIG. 7(b) are cross-sectional views illustrating a cell region Rc of a semiconductor device including a vertical MOS transistor according to a third embodiment of the present disclosure;

FIG. 8 is a diagram illustrating a layout of the semiconductor device illustrated in FIG. 7(a) and FIG. 7(b);

FIG. 9 is a cross-sectional view illustrating a cell region Rc of a semiconductor device including a vertical MOS transistor according to a fourth embodiment of the present disclosure;

FIG. 10 is a diagram illustrating a top layout of a semiconductor device including a vertical MOS transistor according to a fifth embodiment of the present disclosure;

FIG. 11 is a cross-sectional view illustrating a cell region Rc of a semiconductor device including a vertical MOS transistor according to a sixth embodiment of the present disclosure;

FIG. 12 is a cross-sectional view illustrating a cell region Rc of a semiconductor device including a vertical MOS transistor manufactured by a manufacturing method according to a seventh embodiment of the present disclosure;

FIG. 13(a) and FIG. 13(b) are cross-sectional views illustrating examples of cases where a shape of second trenches 10 is different from a shape of first trenches 7;

FIG. 14(a) and FIG. 14(b) are diagrams illustrating top layouts that indicate forming positions of second trenches 10 according to other embodiments; and

FIG. 15(a) is a diagram illustrating an electric field strength distribution in a depth direction in a case where a dummy gate structure is applied to a MOS transistor having a super junction structure, FIG. 15(b) is a diagram illustrating an electric field strength distribution in a depth direction in a case where a dummy gate structure is applied to a DMOS, and FIG. 15(c) is a diagram illustrating an electric field strength distribution in a depth direction in a case where a dummy gate structure is applied to an IGBT.

### EMBODIMENTS FOR CARRYING OUT INVENTION

### First Embodiment

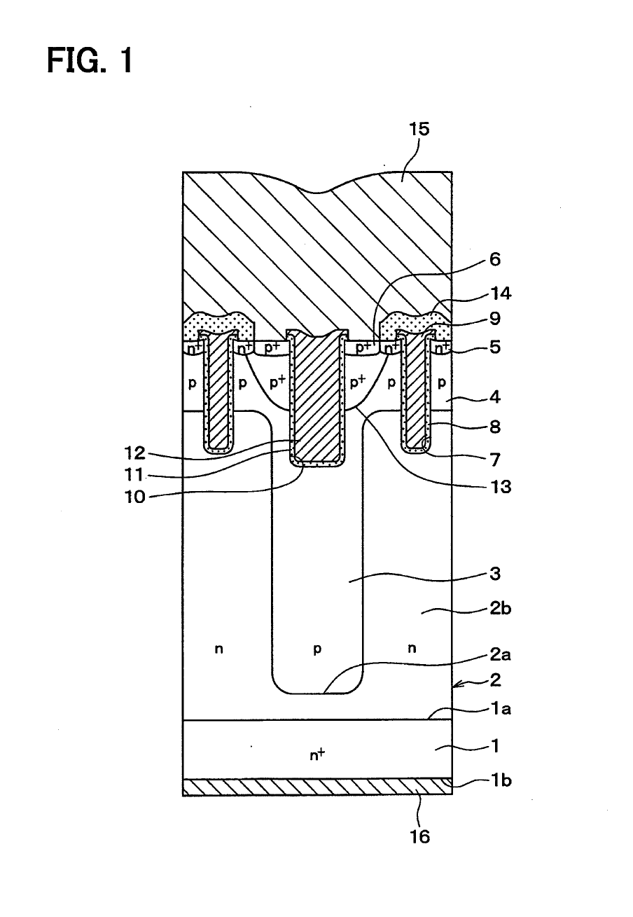

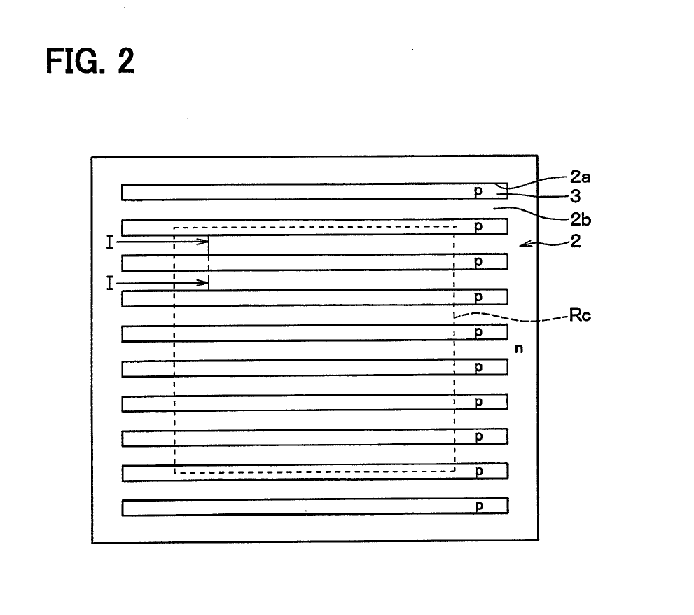

A first embodiment of the present disclosure will be described. In the present embodiment, a semiconductor device that includes a vertical MOS transistor as a vertical semiconductor element will be described as an example. FIG. 1 is a cross-sectional view illustrating a cell region Rc of a semiconductor device including a vertical MOS transistor according to the present embodiment. FIG. 2 is a diagram illustrating a layout of the semiconductor device illustrated in FIG. 1. FIG. 1 corresponds to a cross-sectional view taken along line I-I in FIG. 2.

In the semiconductor device according to the present embodiment illustrated in FIG. 1, an inverted vertical MOS transistor having a trench gate structure is provided as a vertical MOS transistor. As illustrated in FIG. 1, the vertical MOS transistor is formed using an n⁺ type substrate 1 made of single crystal semiconductor such as single crystal silicon. In the n⁺ type substrate 1, one surface is referred to as a main surface 1a and an opposite surface is referred to as a rear surface 1b. The n⁺ type substrate 1 has an impurity concentration of, for example, 1×10¹⁹ cm⁻³. Above the main surface 1a of the n⁺ type substrate 1, an n type drift layer 2 is formed. The n type drift layer 2 has an n type impurity concentration of, for example, 8.0×10¹⁵ cm⁻³.

In the n type drift layer 2, as illustrated in FIG. 2, a plurality of trenches 2a each having a strip shape and each having a longitudinal direction in one direction (a left to right direction over a paper sheet with FIG. 2) is arranged at equal intervals in a direction perpendicular to longitudinal direction. P type regions (p type columns) 3 having a p type impurity concentration of, for example, 8.0×10¹⁵ cm⁻³ are formed so as to fill inside of the trenches 2a as illustrated in FIG. 1. Accordingly, as illustrated in FIG. 1 and FIG. 2, portions of the n type drift layer 2 remaining between the trenches 2a become n type regions (n type columns) 2b, and the n type region 2b and the p type region 3 are alternately and repeatedly formed in a stripe pattern to form a super junction structure.

For example, when a breakdown voltage is anticipated at about 600 V due to the super junction structure, a depth of the n type drift layer 2 is set to 30 through 50 for example, 45 μm, a pitch (a column pitch) between the n type region 2b and the p type region 3 is set to 6.0 a ratio of widths of the n type region 2b and the p type region 3 is set to 1:1, and an area ratio of the cell region Rc is set to 1:1.

On surfaces of the n type regions 2b and the p type regions 3, a p type base region 4 is formed. For example, the p type base region 4 has a p type impurity concentration of 1.0×10¹⁷ cm⁻³ and has a depth of 1.0 μm. At a surface of the p type base region 4, n⁺ type impurity regions 5 and p⁺ type contact regions 6 are formed. The n⁺ type impurity regions 5 have an impurity concentration higher than the n type drift layer 2 and become a source region. The p⁺ type contact regions 6 have an impurity concentration higher than the p type base region 4. The n⁺ type impurity regions 5 have an n type impurity concentration of 1.0×10²° cm⁻³ and have a depth of 0.4 μm, for example. The p⁺ type contact regions 6 have a p type impurity concentration of 1.0×10²⁰ cm⁻³ and have a depth of 0.4 μm, for example.

A plurality of first trenches 7 penetrating the n⁺ impurity region 5 and the p⁺ type base region 4 to reach the n type region 2b and having a longitudinal direction in a direction perpendicular to a paper sheet is arranged at equal intervals. In the present embodiment, the first trenches 7 are formed at positions where the n type regions 2b are formed, and the p type regions 3 are disposed between the adjacent first trenches 7. Gate insulation films 8 are formed to cover surfaces of the first trenches 7, and gate electrodes 9 made of, for example, doped Poly-Si are formed on surfaces of the gate insulation films 8 to fill the first trenches 7. These form a trench gate structure. The first trenches 7 forming the trench gate structure are not illustrated in FIG. 2. However, in the present embodiment, the first trenches 7 extend in the longitudinal direction that is the same direction as the longitudinal direction of the trenches 2a for forming the super junction structure. For example, each of the first trenches 7 has a depth of 3.5 μm and a width of 1.0 μm.

Similarly, between the first trenches 7, second trenches 10 penetrate the p⁺ type base region 4 to reach the p type regions 3. The second trenches 10 have a longitudinal direction in a direction perpendicular to the paper sheet. In the present embodiment, the first trenches 7 are formed at positions where the p type regions 3 are formed. To cover surfaces of the second trenches 10, gate insulation films 11 are formed. The second trenches 10 are deeper and wider than the first trenches 7. For example, each of the second trenches 10 has a depth of 3.8 μm and a width of 3.0 μm. In the second trenches 10, dummy gate electrodes 12 made of, for example, doped Poly-Si are formed. These form a dummy gate structure.

Furthermore, between the first trenches 7, p⁺ type body layers 13 having a p type impurity concentration higher than the p type base region 4 are formed. For example, each of the p⁺ type body layer 13 has a p type impurity concentration of 1.0×10¹⁹ cm⁻³, and has a depth of 2.0 μm, which is shallower than the first trenches 7 and the second trenches 10.

Above the trench gate structure, an interlayer insulation film 14 is formed to cover the gate electrodes 9. In addition, a front surface electrode 15 forming a source electrode is formed. The front surface electrode 15 is electrically connected with the n⁺ type impurity regions 5, the p⁺ type contact regions 6, and the dummy gate electrodes 12 through contact holes formed in the interlayer insulation film 14. In addition, a rear surface electrode 16 serving as a drain electrode is formed on the rear surface of the n⁺ type substrate 1, which serves as a drain region, and the vertical MOS transistor is formed.

In the vertical MOS transistor having the above-described structure, for example, when a gate voltage is not applied to the gate electrode 9, a channel is not formed at the surface portion of the p type base region 4, and electric current between the front surface electrode 15 and the rear surface electrode 16 is interrupted. When a gate voltage is applied, a conductivity-type of a portion of the p type base region 4 being in contact with a side surface of the first trench 7 is reversed in accordance with a voltage value of the gate voltage to form a channel, and electric current flows between the front surface electrode 15 and the rear surface electrode 16.

In addition, in the vertical MOS transistor having the above-described structure, bottom portions of the second trenches 10, which form the dummy gate structure, is deeper than bottom portions of the first trenches 7, which form the trench gate structure. Thus, electric field concentration occurs at the bottom portions of the second trenches 10, and an avalanche breakdown occurs at the bottom portions. Then, holes generated by the avalanche breakdown are extracted along the side surfaces of the second trenches 10 to the front surface electrode 15 through the p⁺ type contact regions 6. Thus, holes can be restricted from approaching a parasitic bipolar transistor formed by the n⁺ type impurity region 5, the p type base region 4, and the n⁻ type drift layer 2, and operation of the parasitic bipolar transistor can be restricted. Accordingly, an avalanche resistance can be improved.

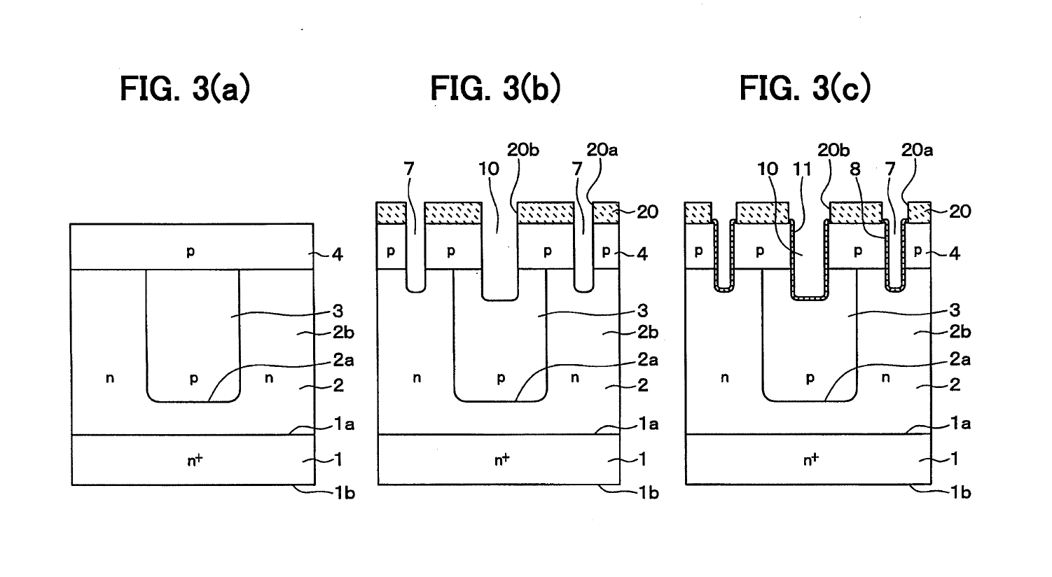

Subsequently, a manufacturing method of the semiconductor device including the vertical transistor according to the present embodiment will be described with reference to FIG. 3(a) through FIG. 5(c). In the semiconductor device, a lower part is not illustrated.

In a process illustrated in FIG. 3(a), after the n⁻ type drift layer 2 is formed by epitaxial growth on the main surface 1a of the n⁺ type substrate 1, a mask having openings at positions where the p type regions 3 will be formed is disposed on the surface of the n⁻ type drift layer 2, and the n⁻ type drift layer 2 is selectively etched using the mask to form the trenches 2a. Then, a p type layer is formed, for example, by epitaxial growth, on the surface of the n⁻ type drift layer 2 including inside the trenches 2a. The p type layer remains only inside the trenches 2a through a planarization process, such as etch back, so as to form the p type regions 3. Accordingly, the super junction structure in which the n type regions 2b and the p type regions 3 are alternately arranged at equal intervals in the stripe pattern is formed. After that, the p type base region 4 is formed by epitaxial growth on the surfaces of the n type regions 2b and the p type regions 3.

In a process illustrated in FIG. 3(b), a mask 20 is disposed on the surface of the p type base region 4. The mask 20 is opened by a photolithography process at positions where the first trenches 7 and the second trenches 10 will be formed. At this time, widths of opening portions formed in the mask 20 correspond to the widths of the first trenches 7 and the second trenches 10. Thus, widths of opening portions 20b formed at positions where the second trenches 10 will be formed are wider than widths of opening portions 20a formed at positions where the first trenches 7 will be formed. Then, by etching using the mask 20, the first trenches 7 and the second trenches 10 are formed. Accordingly, the first and second trenches 7, 10 are formed with the widths corresponding to the opening portions 20a, 20b, respectively. At this time, because the widths of opening portions 20b formed at the positions where the second trenches 10 will be formed are wider than widths of the opening portions 20a formed at the positions where the first trenches 7 will be formed, when the trenches are formed, the second trenches 10 are formed deeper than the first trenches 7 due to a micro loading effect.

In a process illustrated in FIG. 3(c), a gate oxidation process is performed in a state where the mask 20 is disposed so as to form the gate insulation films 8, 11 made of gate oxide films on the inner walls of the first trenches 7 and the second trenches 10.

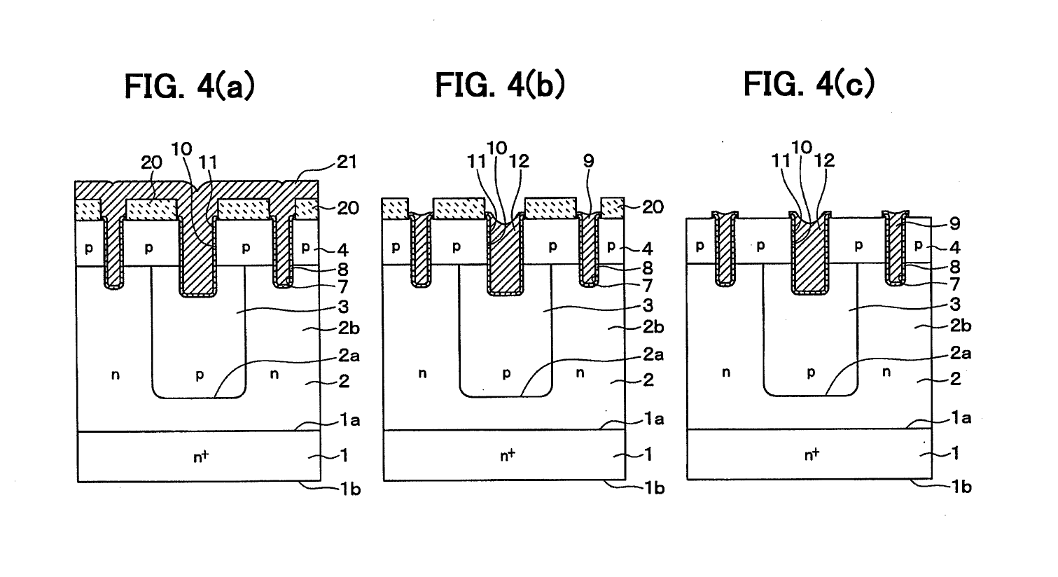

In a process illustrated in FIG. 4(a), a conductive layer 21 made of doped Poly-Si is deposited on the whole surface including inside the first trenches 7 and the second trenches 10. Next, in a process illustrated in FIG. 4(b), unnecessary portions of the conductive layer 21 are removed by etch back so that the conductive layer 21 remains only inside the first trenches 7 and the second trenches 10. Accordingly, the gate electrodes 9 are formed inside the first trenches 7 and the dummy gate electrodes 12 are formed inside the second trenches 10. After that, in a process illustrated in FIG. 4(c), the mask 20 is removed.

Although it is not illustrated, an ion implantation of n type impurities and an ion implantation of p type impurities are performed to the surface portion of the p type base region 4 to form the n⁺ type impurity regions 5 and the p⁺ type contact regions 6. These are formed by repeatedly performing a forming process of a mask having opening at positions where respective regions will be formed and an ion implantation process to the surface of the p⁺ type base region 4. Although the n⁺ type impurity regions 5 and the p⁺ type contact regions 6 are formed after forming the trench gate structure, the n⁺ type impurity region 5 and the p⁺ type contact regions 6 may also be formed after forming the p type base region 4 and before forming the trench gate structure.

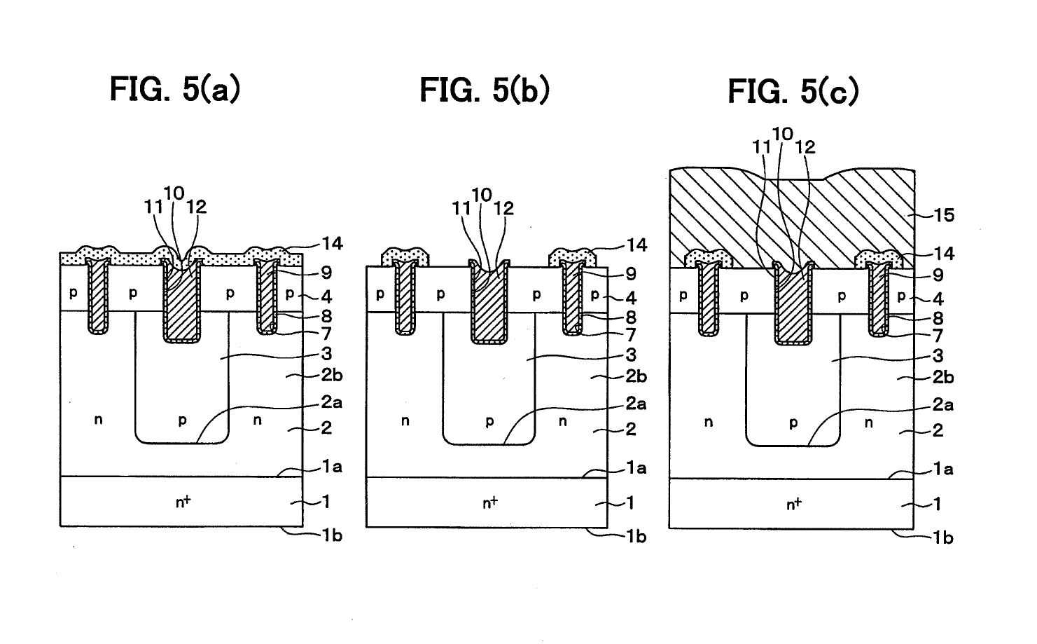

In a process illustrated in FIG. 5(a), the interlayer insulation film 14 is deposited using, for example, an oxide film. Subsequently, in a process illustrated in FIG. 5(b), the interlayer insulation film 14 is selectively etched using a mask, which is not illustrated, to form the contact holes. Although it is not illustrated, after forming the contact holes, p type impurities are ion-implanted through the contact holes using the interlayer insulation film 14 as a mask, and the p type impurities are diffused by a heat treatment to form the p⁺ type body layer 13. In the present embodiment, the p⁺ type body layer 13 is formed to be shallower than the first trenches 7 and the second trenches 10. Thus, a high-temperature and long-time heat treatment as the conventional art is unnecessary. Thus, the present embodiment can restrict generation of a problem that the impurities in the n type regions 2b of the current path of the super junction structure and the impurities in the p type region 3 for charge compensation are diffused each other, charges are compensated, and an on-resistance increases. After that, in a process illustrated in FIG. 5(c), the front surface electrode 15 forming the source electrode is formed, for example, by forming an Al layer. Then, although it is not illustrated, the rear surface electrode 16 forming the drain electrode is formed on the rear surface of the n⁺ type substrate 1, and the semiconductor including the vertical MOS transistor and illustrated in FIG. 1 can be manufactured.

As described above, in the semiconductor device including the vertical MOS transistor according to the present embodiment, the bottom portion of the second trenches 10 forming the dummy gate structure is located at positions deeper than the bottom portions of the first trenches 7 forming the trench gate structure. Thus, an electric field concentration occurs at the bottom portions of the second trenches 10, and an avalanche breakdown occurs at the bottom portions. Then, holes generated by the avalanche breakdown can be extracted along the side surfaces of the second trenches 10 to the front surface electrode 15 through the p⁺ type contact regions 6. Thus, the holes can be restricted from approaching a parasitic bipolar transistor formed by the n⁺ type impurity region 5, the p type base region 4, and the n⁻ type drift layer 2, and operation of the parasitic bipolar transistor can be restricted. Accordingly, the avalanche resistance can be improved.

Because the avalanche resistance can be improved by the structure in which the second trenches 10 are deeper than the first trenches 7, it is not necessary to form the p⁺ type body layer 13 to be deeper than the trench gate structure. Thus, it is not necessary to perform the heat treatment in the forming process of the p⁺ type body layer 13 at high-temperature for a long time as the conventional art. Thus, the present embodiment can restrict generation of a problem that the impurities in the n type regions 2b of the current path of the super junction structure and the impurities in the p type region 3 for charge compensation are diffused each other, the charges are compensated, and the on-resistance increases. Although formation of the p⁺ type body layer 13 is unnecessary, formation of the p⁺ type body layer 13 makes extraction of the holes easy. Thus, operation of the bipolar transistor can be more restricted, and the avalanche resistance can be more improved.

Furthermore, as the present embodiment, when the dummy gate structure is formed at positions where the p type regions 3 are formed in the super junction structure, the trench gate structures are formed at all positions where the n type regions 2b are formed. Thus, a forming area of the trench gate structure per the same chip area increases, and the on-resistance can be reduced.

### Second Embodiment

A second embodiment of the present disclosure will be described. In the present embodiment, a configuration of the super junction structure is changed with respect to the first embodiment, and the other part is similar to the first embodiment. Thus, only a part different from the first embodiment will be described.

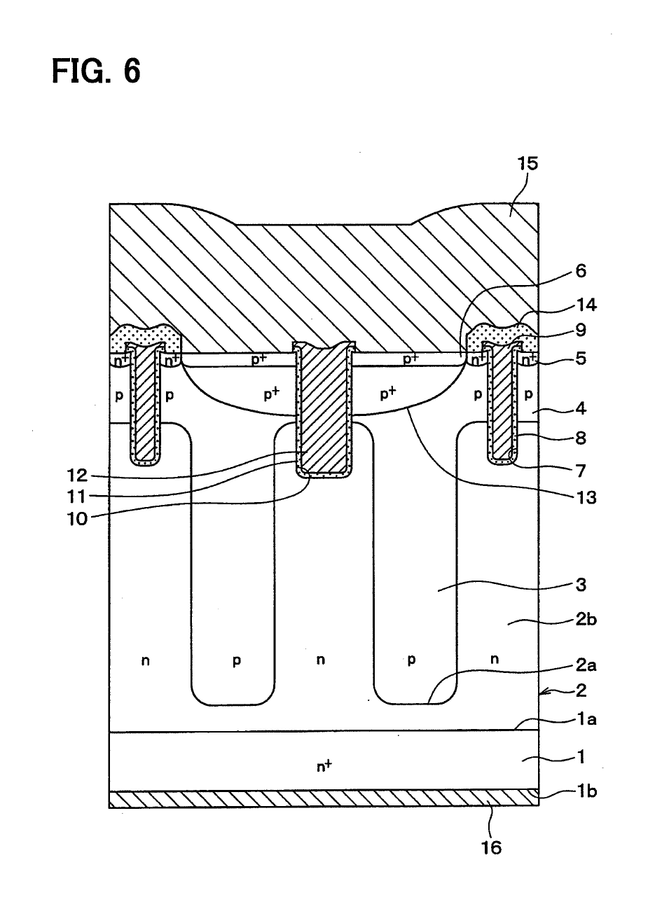

FIG. 6 is a cross-sectional view illustrating a cell region Rc of the semiconductor device including the vertical MOS transistor according to the present embodiment. As illustrated in FIG. 6, in the present embodiment, the dummy gate structure is formed at the positions where the n type regions 2b are formed. Specifically, the longitudinal directions of the first trenches 7 and the second trenches 10 are set to be the same direction as the longitudinal directions of the n type region 2b and the p type regions 3. The first trenches 7 are disposed in every other n type regions 2b, and the second trenches 10 are formed at parts of the n type regions 2b in which the first trenches 7 are not formed.

In this way, the dummy gate structure may be formed at positions where the n type regions 2b are formed. In a case with the above-described structure, because the second trenches 10 are disposed at the positions where the n type regions 2b are formed, the number of the first trenches 7 is limited. Thus, compared with the first embodiment, the forming area of the trench gate structure per the same chip area is reduced. In view of reduction of the on-resistance, the structure of the first embodiment has an advantage. However, when an equipotential distribution in the super junction structure is confirmed, a potential distribution is less likely to expand in the p type regions 3 compared with the n type regions 2b. Thus, compared with a case where the dummy gate structure is disposed at the positions where the n type regions 2b are formed, an advantage due to the depth of the dummy gate structure is less likely to be obtained. Thus, in the structure according to the present embodiment, by forming the dummy gate structure to be deeper, a generation position of an avalanche breakdown can be easily controlled, the operation of the parasitic bipolar transistor can be restricted more certainty, and the avalanche resistance can be improved.

### Third Embodiment

A third embodiment of the present disclosure will be described. In the present embodiment, a configuration of the super junction structure is changed with respect to the first embodiment, and the other part is similar to the first embodiment. Thus, only a part different from the first embodiment will be described.

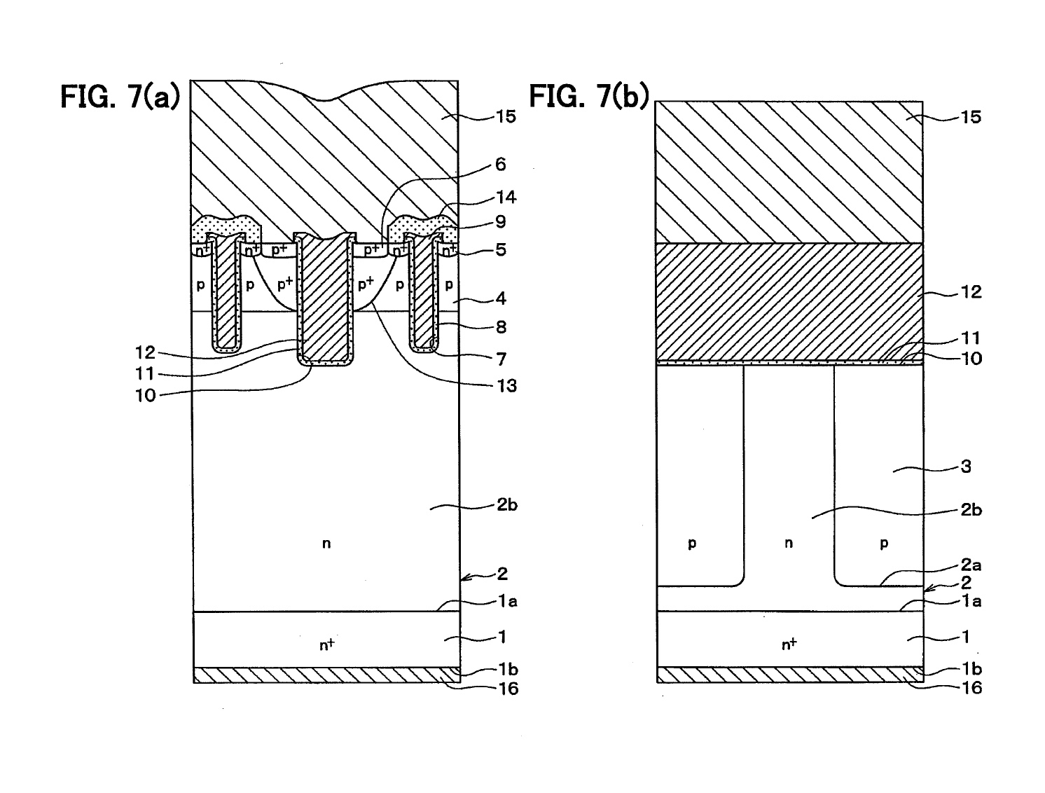

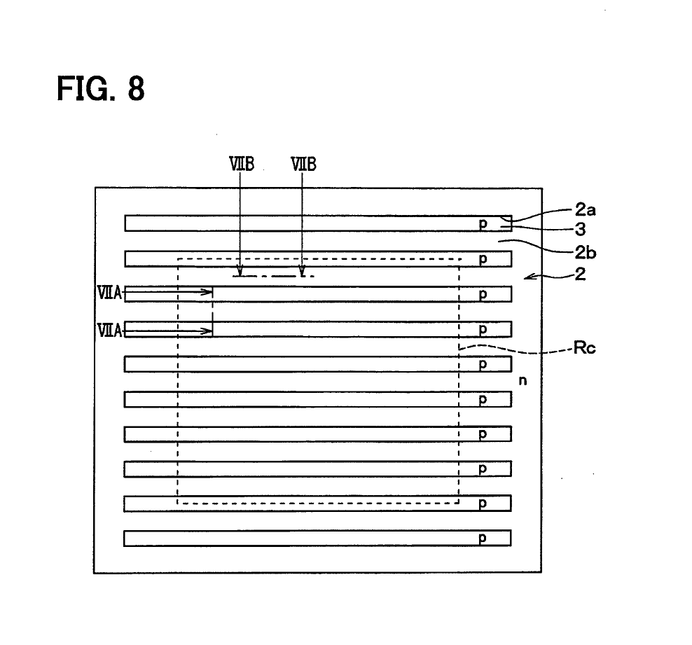

FIG. 7(a) and FIG. 7(b) are cross-sectional views illustrating a cell region Rc of the semiconductor device including the vertical MOS transistor according to the present embodiment. FIG. 8 is a diagram illustrating a layout of the semiconductor device illustrated in FIG. 7. FIG. 7(a) and FIG. 7(b) respectively correspond to cross-sectional view taken along lines VIIA-VIIIA, VIIB-VIIB in FIG. 8.

As illustrated in FIG. 7(a), (b) and FIG. 8, in the present embodiment, the longitudinal directions of the first trenches 7 and the second trenches 10 are set to intersect with the longitudinal directions of the n type regions 2b and the p type regions 3 so that the longitudinal directions of the trench gate structure and the dummy gate structure intersect with the longitudinal direction of the super junction structure. In this way, also in the structure in which the longitudinal directions of the trench gate structure and the dummy gate structure intersect with the longitudinal direction of the super junction structure, the same effects as the first embodiment can be obtained.

### Fourth Embodiment

A fourth embodiment of the present disclosure will be described. In the present embodiment, a configuration in the vicinity of the dummy gate structure is changed with respect to the first embodiment, and the other part is similar to the first embodiment. Thus, only a part different from the first embodiment will be described.

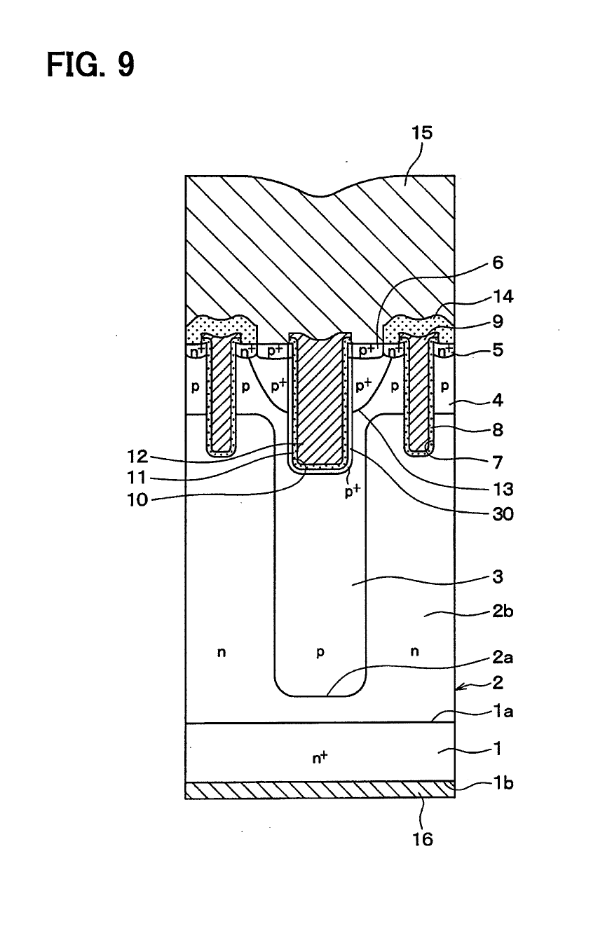

FIG. 9 is a cross-sectional view illustrating a cell region Rc of a semiconductor device including a vertical MOS transistor according to the present embodiment. As illustrated in FIG. 9, in the present embodiment, p type high concentration regions 30 having a p type impurity concentration higher than the p type base region 4 are disposed along the inner walls of the second trenches 10. In a case where the p type high concentration regions 30 are formed as described above, when an avalanche breakdown occurs, holes can be extracted from the p type high concentration regions 30 of a low resistance. Thus, the holes can be extracted more easily.

Note that the above-described configuration can be manufactured by a manufacturing method basically similar to the manufacturing method of the semiconductor device according to the first embodiment. For example, after the process illustrated in FIG. 3(c), a process in which a mask covering the first trenches 7 and exposing the second trenches 10 is disposed and p type impurities are ion-implanted from above the mask to form the p type high concentration regions 30 may be added.

### Fifth Embodiment

A fifth embodiment of the present disclosure will be described. In the present embodiment, a layout of the super junction structure is changed with respect to the first embodiment, and the other part is similar to the first embodiment. Thus, only a part different from the first embodiment will be described.

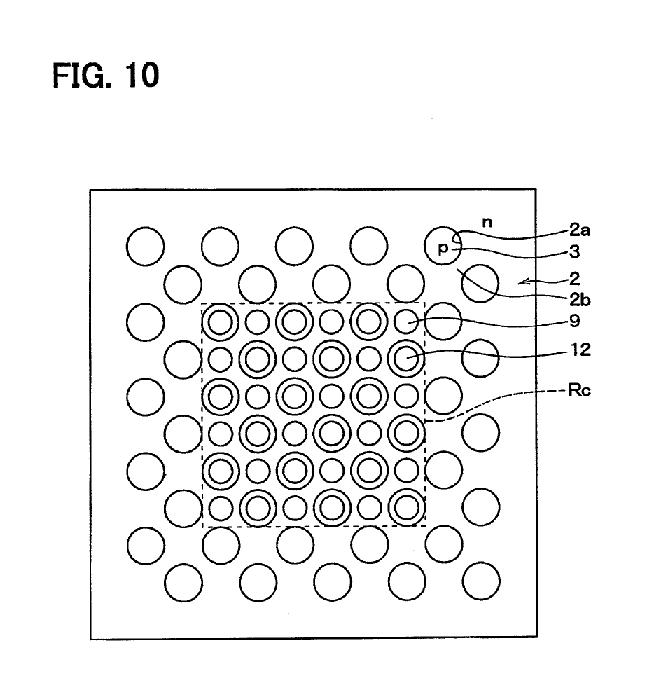

FIG. 10 is a diagram illustrating a top layout of a semiconductor device including a vertical MOS transistor according to the present embodiment. As illustrated in FIG. 10, in the present embodiment, the p type regions 3 forming the p type columns are arranged in a dotted pattern with respect to the n type region 2b forming the n type columns. In the cell region Rc, the dummy gate electrodes 12 are arranged at positions corresponding to the p type regions 3, and the normal gate electrodes 9 are disposed in the n type regions 2b between the dummy gate electrodes 12.

Like this, the n type region 2b and the p type region 3 may also be alternately repeated from the center of the cell region Rc in the radial direction by arranging the p type region 3 in the dotted pattern, not by alternately arranging the n type region 2b and the p type region 3 in the stripe pattern.

### Sixth Embodiment

A sixth embodiment of the present disclosure will be described. In the present embodiment, a connection destination of the dummy gate electrodes 12 is changed with respect to the first embodiment, and the other part is similar to the first embodiment. Thus, only a part different from the first embodiment will be described.

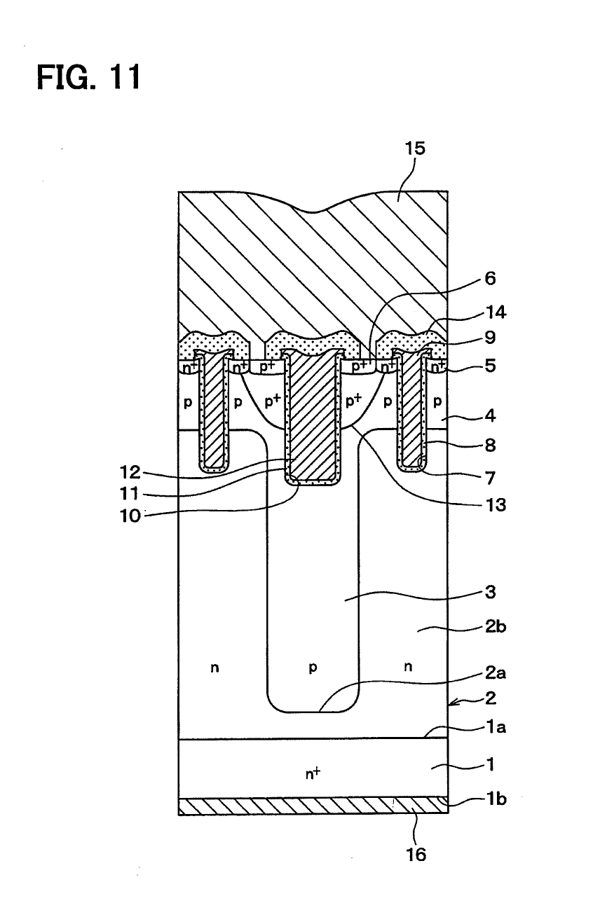

FIG. 11 is a cross-sectional view illustrating a cell region Rc of a semiconductor device including a vertical MOS transistor according to the present embodiment. As illustrated in FIG. 11, in the present embodiment, the interlayer insulation film 14 is disposed also on the surface of the dummy gate electrodes 12 so that the front surface electrode 15 forming the source electrode is insulated from the dummy gate electrodes 12. The dummy gate electrodes 12 are electrically connected to the gate electrodes 9 on a cross section different from the cross section illustrated in FIG. 11 so that the dummy gate electrodes 12 are fixed to a gate potential.

Like this, the dummy gate electrodes 12 can also be fixed to the gate potential not to the source potential. Note that the dummy gate electrodes 12 can be in a floating state. However, it is preferable to fix the dummy gate electrodes 12 to the source potential or the gate potential so that an avalanche breakdown occurs certainly at the dummy gate electrodes 12. In a case where the dummy gate electrodes 12 are in the floating state, a change (curve) in equipotential lines in semiconductor is smaller than a case where the dummy gate electrodes 12 are fixed to a potential. Thus, it is preferable to fix the dummy gate electrodes 12 to the potential in order to generate more electric field concentration due to a large change in equipotential lines and to cause an avalanche breakdown more easily.

### Seventh Embodiment

A seventh embodiment of the present embodiment will be described. In the above-described first embodiment, the trenches 2a are formed with respect to the n type drift layer 2, and the p type regions 3 are formed in the trenches 2a to fill the trenches 2a. However, the p type regions 3 can also be formed by an ion implantation to the n type drift layer 2.

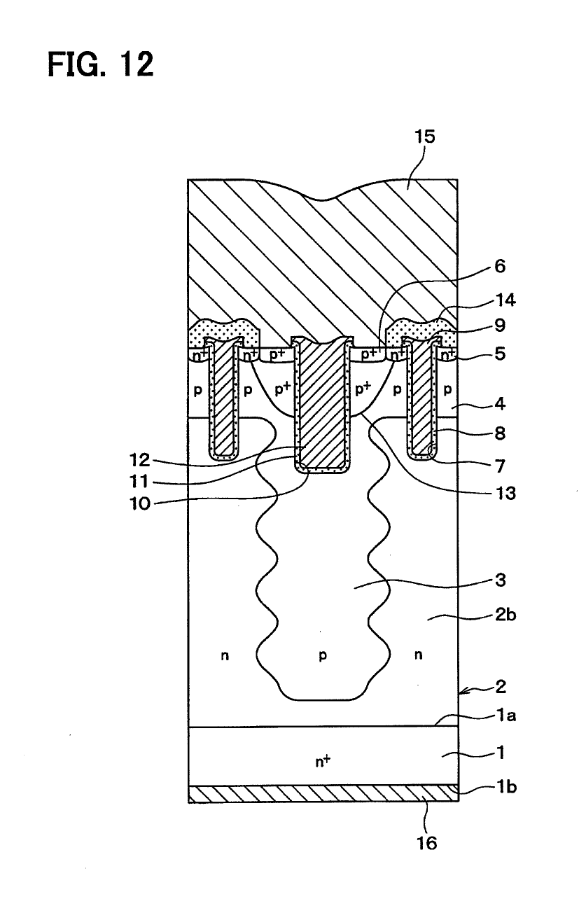

Specifically, after a part of the whole thickness of the n type drift layer 2 is formed by epitaxial growth above the main surface 1a of the n⁺ type substrate 1, the p type impurities are ion-implanted to the portions where the p type regions 3 will be formed. Then, after a part of the whole thickness of the n type drift layer 2 is further formed by epitaxial growth, the p type impurities are ion-implanted to portions where the p type regions 3 will be formed. Also after that, an epitaxial growth of a part of the whole thickness of the n type drift layer 2 and an ion implantation process of the p type impurities to form the p type regions 3 are repeated and a heat treatment is performed so that the n type drift layer 2 is formed to have a desired thickness and the p type regions 3 are formed at positions of the ion implantation. Accordingly, even when a forming depth of the p type regions 3 is deep, the p type regions 3 can be formed by ion implantation. In a case where the p type regions 3 are formed by the above-described way, the p type impurities implanted in each of the ion implantation processes are thermally diffused to equal distance from the positions where the p type impurities are implanted. Thus, the p type regions 3 have a shape in which a width changes in multiple stages as illustrated in FIG. 12. However, the super junction structure can function without any problem.

As described above, the p type regions 3 can also be formed by the ion implantation of the p type impurities to the n type drift layer 2 not by filling the trenches 2a formed in the n type drift layer 2.

### Other Embodiments

In each of the above-described embodiments, the second trenches 10 for forming the dummy gate structure are disposed between the first trenches 7 for forming the trench gate structure. A forming ratio of the second trenches 10 to the first trenches 7 may be set optionally. In other words, it is not necessary to form the second trenches 10 between all the first trenches 7. One line of the second trenches 10 may be formed for every multiple lines of the first trenches 7.

In the fourth embodiment, the case where the p type high concentration regions 30 are formed with respect to the configuration of the first embodiment has been described. However, the p type concentration regions 30 may be formed with respect to the second or the third embodiment.

In each of the above-described embodiments, the case where the manufacturing process is simplified by forming the first trenches 7 and the second trenches 10 at the same time has been described. However, it is not always necessary to form the first trenches 7 and the second trenches 10 at the same time. In other words, it is only necessary to form the second trenches 10 for forming the dummy gate structure to be deeper than the first trenches 7 for forming the trench gate structure and it is not always necessary to form the first trenches 7 and the second trenches 10 at the same time. In a case where the first trenches 7 and the second trenches 10 are not formed at the same time, it is not necessary to set the width of the second trenches 10 to be wider than the width of the first trenches 7. When the width of the second trenches 10 is set to be narrower than the width of the first trenches 7, an avalanche breakdown occurs more likely to occur at the bottom portions of the second trenches 10.

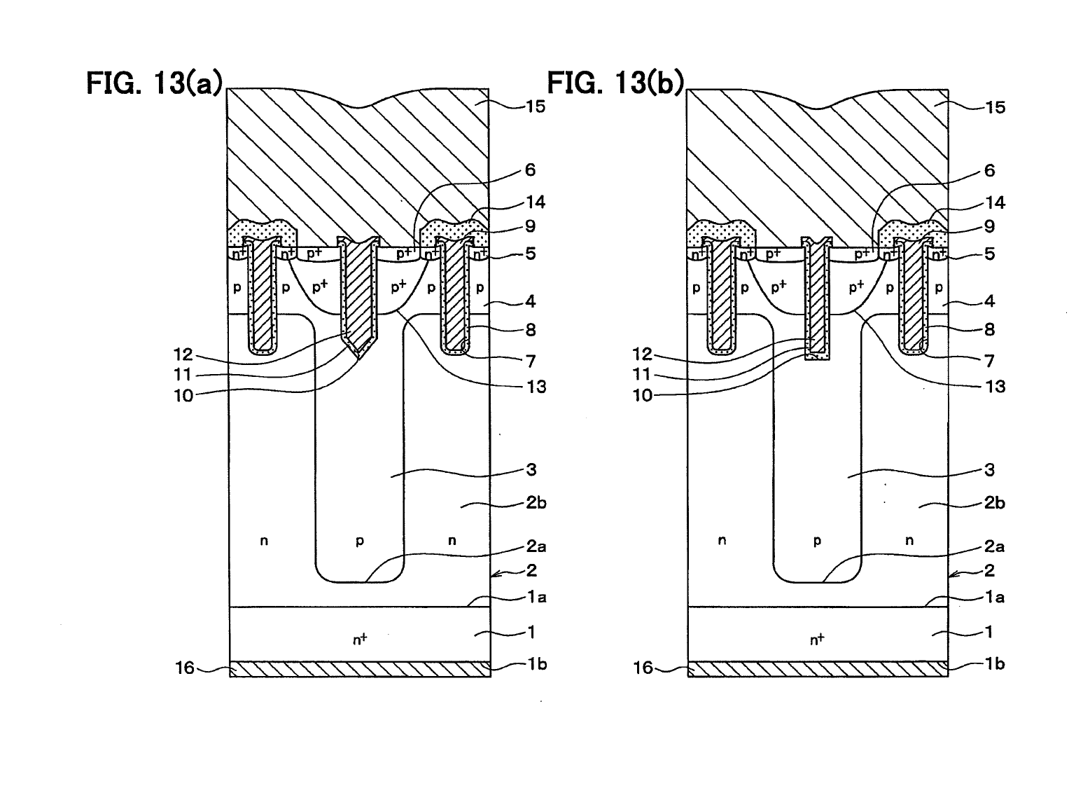

In each of the above-described embodiments, the shape of the second trenches 10 for forming the dummy gate structure may be different from the shape of the first trenches 7 so that an avalanche breakdown is likely to occur at the bottom portions of the second trenches 10. FIG. 13(a) and FIG. 13(b) are cross-sectional views illustrating examples of cases where a shape of the second trenches 10 are different from a shape of the first trenches 7.

In FIG. 13(a), the second trench 10 has a taper shape in which the width is narrowed toward an end, and the end of the second trench 10 has an acute angle and is pointed. When the second trenches 10 have such shapes, electric field concentration can be likely to occur at the ends of the second trenches 10 forming the dummy gate structure, and an avalanche breakdown can be likely to occur at the bottom portions of the second trenches 10.

In FIG. 13(b), the width of the second trenches 10 is set to be narrower than the width of the first trenches 7 as described above. When the width of the second trenches 10 is set to be narrower than the width of the first trenches 7, an avalanche breakdown can be likely to occur at the bottom portions of the second trenches 10.

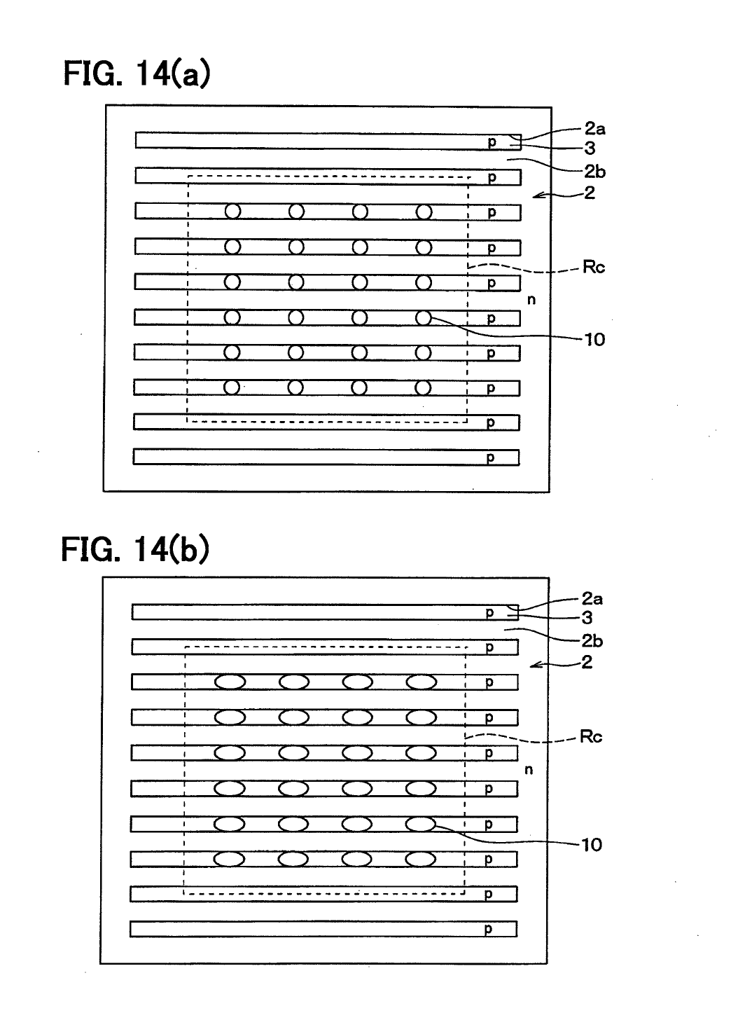

Furthermore, by limiting the forming positions of the second trenches 10, an avalanche breakdown is more likely to occur at the bottom portions of the second trenches 10. FIG. 14(a) and FIG. 14(b) are diagrams illustrating top layouts that indicate forming positions of the second trenches 10. As illustrated in FIG. 14(a), the second trenches 10 may be scattered in a dotted pattern. As illustrated in FIG. 14(b), the second trenches 10 having a length in the longitudinal directions of the p type columns and the n type columns may also be scattered. When the second trenches 10 are not arranged in a stripe pattern in the whole area of the cell region Rc, but are scattered, electric field is more likely to concentrate at the dummy gate structure compared with a case with the stripe pattern. Thus, an avalanche breakdown is more likely to occur at the bottom portions of the second trenches 10.

In the above-described embodiments, an n channel type MOS transistor in which a first conductivity-type is n type and a second conductivity-type is p type has been described. However, the present disclosure can also be applied to a p channel type MOS transistor in which conductivity-types of respective components forming elements are inversed. In addition, not limited to the MOS transistors, the present disclosure can also be applied to an IGBT, and a configuration similar to each of the above-described configuration can be applied. In this case, a p⁺ type substrate may be used instead of the n⁺ type substrate.

In the above-described embodiments, the trenches 2a are formed to the n⁻ type drift layer 2, and the trenches 2a are filled with the p type regions 3 to form the super junction structure. However, this is one example of a forming method of the super junction structure, and the super junction structure may be formed by other method. For example, when the n⁻ type drift layer 2 is grown, an ion implantation of the p type impurities may be performed to form a part of the p type regions 3 after growing the n⁻ type drift layer 2 for a predetermined thickness, and they may be repeated to form the super junction structure.

In the above-described embodiment, cases where silicon is used as semiconductor material have been described. However, the present disclosure can also be applied to a semiconductor substrate used in a manufacture of a semiconductor device in which other semiconductor material such as silicon carbide or compound semiconductor is used.

The above-described dummy gate structure can be applied to various transistors to which a trench gate structure is applied, such as a MOS transistor, a DMOS, or an IGBT having a super junction structure. Especially when the above-described dummy gate structure is applied to the MOS transistor having the super junction structure, an effect is high. This is because, when a dummy trench structure is included, a breakdown voltage is less likely to decrease in a MOS transistor having a super junction structure than in a DMOS or an IGBT.

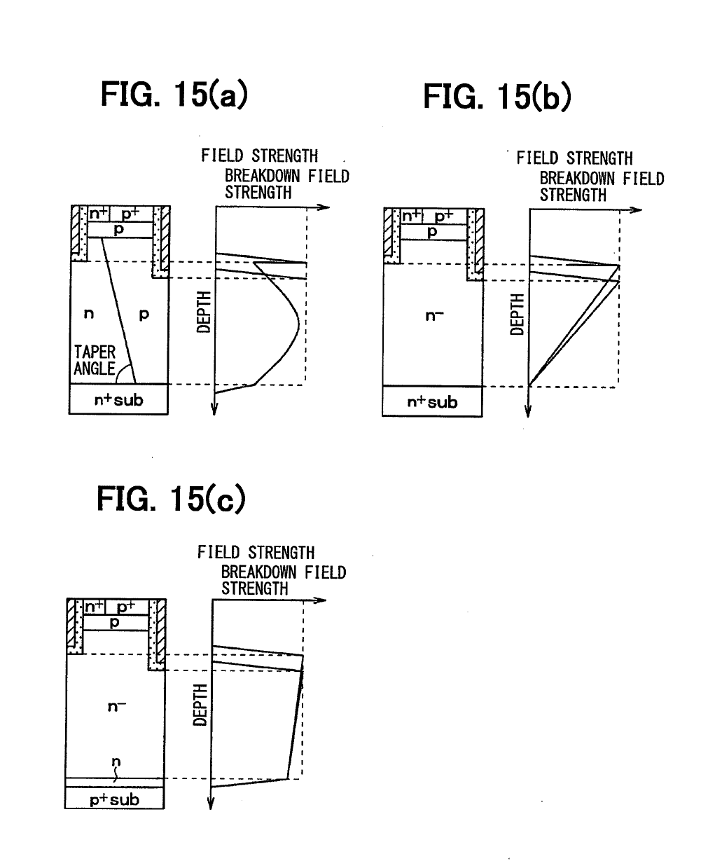

FIG. 15(a) through FIG. 15(c) are diagrams respectively illustrating electric field strength distributions in a depth direction in cases where a dummy gate structure is applied to a MOS transistor having a super junction structure, a DMOS, and an IGBT. As illustrated in theses drawings, the DMOS and the IGBT have distributions in which the electric field strengths in the depth direction become the maximum on the front surface side. On the other hand, in the MOS transistor having the super junction structure, although the electric field strength becomes the maximum just under the gate trenches due to taper structures at boundaries between the n type columns and the p type columns, in other portion, the electric field strength becomes the maximum at middle portions of the columns in the depth direction. Thus, the decrease in the breakdown voltage (integral of the electric field strength and the depth) when the dummy gate structure is applied is smaller in the MOS transistor having the super junction structure than in the DMOS or the IGBT, and the dummy gate structure can be deeper by the amount. Thus, when the dummy gate structure is applied to the MOS transistor having the super junction, a higher effect can be obtained compared with the case where the dummy gate structure is applied to the DMOS or the IGBT.

1. A semiconductor device including a vertical semiconductor element, the vertical semiconductor element comprising:
a semiconductor substrate of a first conductivity-type or a second conductivity-type having a main surface and a rear surface;
a drift layer of the first conductivity-type formed to the main surface side of the semiconductor substrate;
a second conductivity-type region formed to the main surface side of the semiconductor substrate and arranged alternately with the drift layer to form a super junction structure;
a base region of the second conductivity-type formed above the super junction structure;
a first impurity region of the first conductivity-type formed at a surface portion of the base region and having an impurity concentration higher than the drift layer;
a first trench penetrating the first impurity region and the base region to reach a first conductivity-type region formed by the drift layer in the super junction structure;
a first gate insulation film formed on an inner wall of the first trench;
a gate electrode formed on a surface of the first gate insulation film and filling the first trench to form a trench gate structure;
a contact region of the second conductivity-type formed at the surface portion of the base region on an opposite side of the first impurity region from the first trench, the contact region having an impurity concentration higher than the base region;
a front surface electrode electrically connected to the first impurity region and the contact region;
a rear surface electrode electrically connected to the semiconductor substrate;
a second trench penetrating the base region to reach the super junction structure and formed to be deeper than the first trench;
a second gate insulation film formed on an inner wall of the second trench; and
a dummy gate electrode formed on a surface of the second gate insulation film and filling the second trench to form a dummy gate structure,
wherein electric current flows between the front surface electrode and the rear surface electrode based on voltage application to the gate electrode.

2. The semiconductor device according to claim 1,
wherein the vertical semiconductor element further includes a body layer of the second conductivity-type having an impurity concentration higher than the base region,
wherein a plurality of the first trenches extends in a first direction and is arranged in a second direction perpendicular to the first direction, and
wherein the body layer is disposed between adjacent two lines of the first trenches.

3. The semiconductor device according to claim 1,
wherein the super junction structure is formed by alternately arranging the drift layer and the second conductivity-type region in a stripe pattern,
wherein a plurality of the first trenches extends in a first direction and is arranged in a second direction perpendicular to the first direction,
wherein the first conductivity-type region and the second conductivity-type region extend in the first direction, and
wherein the second trench extends in the first direction between adjacent two lines of the first trenches and is formed at a position where the second conductivity-type region is formed.

4. The semiconductor device according to claim 1,
wherein the super junction structure is formed by alternately arranging the drift layer and the second conductivity-type region in a stripe pattern,
wherein a plurality of the first trenches extends in a first direction and is arranged in a second direction perpendicular to the first direction,
wherein the first conductivity-type region and the second conductivity-type region extend in the first direction, and
wherein the second trench extends in the first direction between adjacent two lines of the first trenches and is formed at a position where the first conductivity-type region is formed.

5. The semiconductor device according to claim 1,
wherein the super junction structure is formed by alternately arranging the drift layer and the second conductivity-type region in a stripe pattern,
wherein a plurality of the first trenches extends in a first direction and is arranged in a second direction perpendicular to the first direction,
wherein the first conductivity-type region and the second conductivity-type region extend in a direction intersecting with the first direction,
wherein the second trench extends in the first direction between adjacent two of the first trenches.

6. The semiconductor device according to claim 2,
wherein one line of the second trench is formed with respect to a plurality of the first trenches.

7. The semiconductor device according to claim 1,
wherein the second trench is scattered in a dotted pattern.

8. The semiconductor device according to claim 1,
wherein the second trench has a taper shape narrowing toward an end.

9. The semiconductor device according to claim 1,
wherein the second trench is narrower than the first trench.

10. The semiconductor device according to claim 1,
wherein the super junction structure is formed by the drift layer and the second-conductivity-type region alternately arranged in a stripe pattern.

11. The semiconductor device according to claim 1,
wherein the super junction structure is formed by arranging the second conductivity-type region in a dotted pattern in the drift layer.

12. The semiconductor device according to claim 1,
wherein the dummy gate electrode is connected to the front surface electrode or the gate electrode.

13. A manufacturing method of a semiconductor device including a vertical semiconductor element, comprising:
preparing a semiconductor substrate of a first conductivity-type or a second conductivity-type having a main surface and a rear surface;
forming a drift layer of the first conductivity-type to the main surface side of the semiconductor substrate and forming a second conductivity-type region in the drift layer to form a super junction structure in which a first conductivity-type region provided by a remaining region of the drift layer at which the second conductivity-type region is not formed and the second conductivity-type region alternately arranged;
forming a base region of the second conductivity-type above the super junction structure;
arranging a mask having a first opening portion and a second opening portion wider than the first opening portion above the base region and forming a first trench having a width corresponding to the first opening portion and a second trench having a width corresponding to the second opening portion and deeper than the first trench by etching using the mask;
forming gate insulation films covering inner walls of the first and second trenches;
forming a trench gate structure by forming a gate electrode on a surface of the gate insulation film in the first trench and forming a dummy structure by forming a dummy gate electrode on a surface of the gate insulation film in the second trench;
forming a first impurity region of the first conductivity-type having an impurity concentration higher than the drift layer at a surface portion of the base region;
forming a contact region of the second conductivity-type at the surface portion of the base region on an opposite side of the first impurity region from the first trench, the contact region having an impurity concentration higher than the base region;
forming a front surface electrode electrically connected to the first impurity region and the contact region; and
forming a rear surface electrode electrically connected to the semiconductor substrate.

14. The manufacturing method according to claim 13,
wherein the forming the super junction structure includes forming a plurality of trenches in the drift layer after forming the drift layer of the first conductivity-type, filling the trench with the second conductivity-type region so the first conductivity-type region provided by a region of the drift layer remaining between the trenches and the second conductivity-type region are alternately arranged.
